(19) United States
(12) Patent Application Publication
(10) Pub. No.: US 2011/0056433 A1
(43) Pub. Date: Mar. 10, 2011

(54) Device for forming diamond film

(75) Inventors: Yuan-Chao Yang, Beijing (CN); Kai-Li Jiang, Beijing (CN); Shou-Shan Fan, Beijing (CN)

(73) Assignees: Tsinghua University, Beijing (CN); HON HAI PRECISION INDUSTRY CO., LTD., Tu-Cheng (TW)

(21) Appl. No.: 12/592,906

(22) Filed: Dec. 3, 2009

(30) Foreign Application Priority Data
Sep. 4, 2009 (CN) 200910190151.7

(51) Int. Cl. C23C 16/44

(52) U.S. Cl. 118/723 R; 977/742

(57) ABSTRACT

A device for forming diamond films includes a reactor chamber, a supporter, a vacuum pump, at least one hot filament, a first electrode and a second electrode. The supporter, the vacuum pump, the at least on hot filament, and the first and second electrodes are received in the reactor chamber. The reactor chamber includes an inlet and an outlet. The vacuum pump is connected with the rector chamber via the inlet. The hot filament includes at least one carbon nanotube wire. The carbon nanotube wire includes a plurality of carbon nanotubes.

### RELATED APPLICATIONS

This application claims all benefits accruing under 35 U.S.C. §119 from China Patent Application No. 200910190151.7, filed on Sep. 4, 2009 in the China Intellectual Property Office.

### BACKGROUND

1. Technical Field

This disclosure relates to devices for forming diamond film, especially to a device for forming diamond film using Hot Filament Chemical Vapor Deposition (HFCVD).

2. Description of Related Art

Thin films of diamond are known to have great potential for use in a variety of applications due to their exceptional mechanical, thermal, optical and electronic properties. For example, diamond films can be used as semiconductors, transistors, heat sinks, optical coatings, optical devices, electronic devices, as coatings for drill bits and cutting tools, and as inert coatings for prosthetics. Thus, there is considerable incentive to find practical ways to synthesize diamond, especially in film form, for these many and varied applications.

Various methods are known for the synthetic production of diamond, including diamond in film form. In particular, the deposition of diamond coatings on substrates to provide films is known. One class of the methods currently developed for synthetic diamond deposition is the low pressure growth of diamond called the chemical vapor deposition (CVD) method.

Diamond films have been grown now by using a variety of deposition techniques, such as hot-filament chemical vapor deposition (HFCVD), microwave plasma CVD (MWCVD), plasma jet and flame jet. Among them, HFCVD is the most extensively used one. The advantage of this method is simplicity of the equipment, easiness of process control, relatively low cost of process and potential of scale-up.

The HFCVD technique involves the use of a dilute mixture of hydrocarbon gas (typically methane) and hydrogen, wherein the hydrocarbon content usually is varied from about 0.1% to 2.5% of the total volumetric flow. The gas is introduced via a quartz tube located just above a hot tungsten filament which is electrically heated to a temperature ranging from between about 1750° C. to about 2400° C. The gas mixture disassociates at the filament surface, and diamonds are condensed onto a heated substrate placed just below the hot tungsten filament. The substrate is heated to a temperature in the region of about 500° C. to about 1100° C.

However, if metal materials are used as a hot filament at a high temperature, the hot filament is easy to carbonize, deform and become brittle, and the metal at high temperatures evaporates, thus, the diamond films obtained contains impurities.

What is needed, therefore, is to provide a device for forming diamond film using HFCVD.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a device using a HFCVD method for growing diamond films.

FIG. 2 is a schematic view of the device in use.

FIG. 3 shows a Scanning Electron Microscope (SEM) image of an untwisted carbon nanotube wire used in the device.

FIG. 4 shows an SEM image of a twisted carbon nanotube wire used in the device.

FIG. 5 is a schematic structural enlarged view of an outer surface of the carbon nanotube wire used in the device.

FIG. 6 is a schematic view of the device in use, wherein the device has a substrate connected in voltage.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

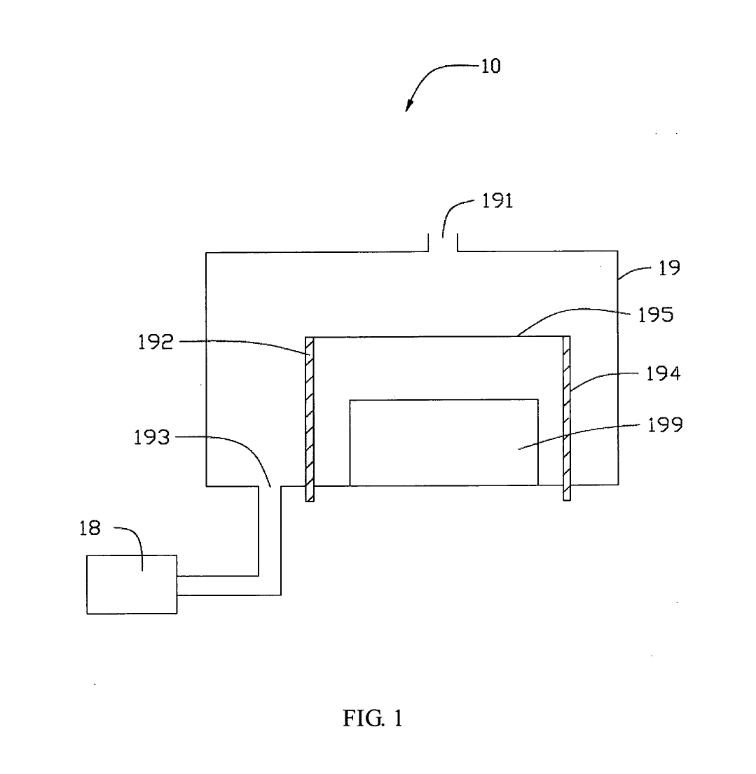

Referring to FIG. 1, one embodiment of an device 10 for forming diamond films includes a reactor chamber 19, a supporter 199, a vacuum pump 18, at least one hot filament 195, a first electrode 192 and a second electrode 194.

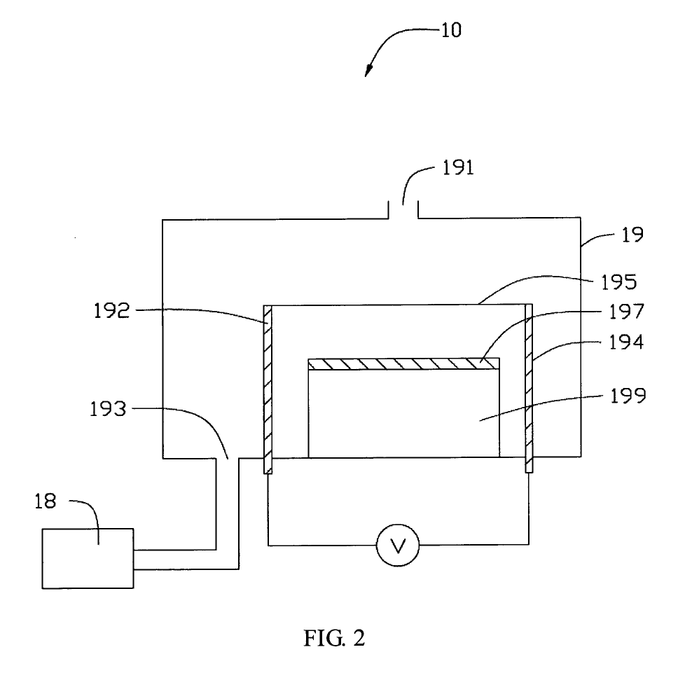

Referring to FIG. 2, a substrate 197 can be located on a top surface of the supporter 199 when the device 10 is in use. The substrate 197 is facing the at least one hot filament 195. The first electrode 192 and the second electrode 194 are electrically connected with the at least one hot filament 195, such that a voltage can be applied across the at least one hot filament 195 via the first and second electrodes 192, 194. A smooth top surface of the substrate 197 is provided for growing a diamond film thereon. The supporter 199 is used to fix the substrate 197 in the reactor chamber 19.

The reactor chamber 19 receives the supporter 199, the substrate 197, the at least one hot filament 195, and the first and second electrodes 192, 194 therein. The reactor chamber 19 has an inlet 191 and an outlet 193. The inlet 191 is configured to introduce a mixture of hydrocarbon gas and hydrogen into the reactor chamber 19, thus producing or acting as a source of carbon atoms for growing diamond films (not shown) on the substrate 197. The supporter 199 is facing and apart from the inlet 191. The at least one hot filament 195 is located between the inlet 191 and the supporter 199, and in front of the inlet 191. The substrate 197 is located on the supporter 199 such that the at least one hot filament 195 is located between the inlet 191 and the substrate 197. The outlet 193 is connected with the vacuum pump 18 and configured for allowing an exhaust gas to be evacuated/discharged from the reactor chamber 19.

The reactor chamber 19 may have any shape, such as a circular, elliptic, triangular, rectangular, regular polygonal or irregular polygonal configuration. The reactor chamber 19 may be made of a material with a high temperature resistance and chemically stable performance. For example, the reactor chamber 19 may be made of quartz, ceramic, stainless steel or the like. In one embodiment, the reactor chamber 19 is a cylinder with a substantially circular cross section.

The supporter 199 can be a rectangular platform base body. The temperature of the supporter 199 can be controlled with a cooling system (not shown) located inside the supporter 199. The cooling system can be used to control the temperature of the substrate 197 located on the supporter 199.

The at least one hot filament 195 can face the inlet 191 to ensure the mixture gas can be heated sufficiently. In one embodiment, a distance between the at least one hot filament 195 and the supporter 199 is in a range from about 5 millimeters to about 15 millimeters.

The first electrode 192 and the second electrode 194 can be located inside the reactor chamber 19. One portion of the first and second electrodes 192,194 can be fixed on and electrically insulated from the reactor chamber 19. Another portion of the first and the second electrodes 192,194 can be connected to the at least one hot filament 195. To provide a voltage on the least one hot filament 195, the first electrode 192 and the second electrode 194 can be electrically connected to an electrical source, such as by conductive wires. The first electrode 192 and the second electrode 194 are made of conductive material. The shape of the first electrode 192 or the second electrode 194 is not limited and can be lamellar, rod, wire, and block shaped, among other shapes. A material of the first electrode 192 or the second electrode 194 can be metal, conductive adhesive, and graphite. In one embodiment, the first and the second electrodes 192, 194 are copper.

The hot filament 195 includes at least one carbon nanotube wire. The carbon nanotube wire comprises a plurality of carbon nanotubes joined with each other via Van der Walls attractive force. The carbon nanotubes are aligned end-to-end along an axis of the carbon nanotube wire and joined by van der Waals attractive force between them. The carbon nanotube wire can be a twisted carbon nanotube wire or untwisted carbon nanotube wire. The carbon nanotubes can be single-walled carbon nanotubes, double-walled carbon nanotubes, multi-walled carbon nanotubes, or combinations thereof.

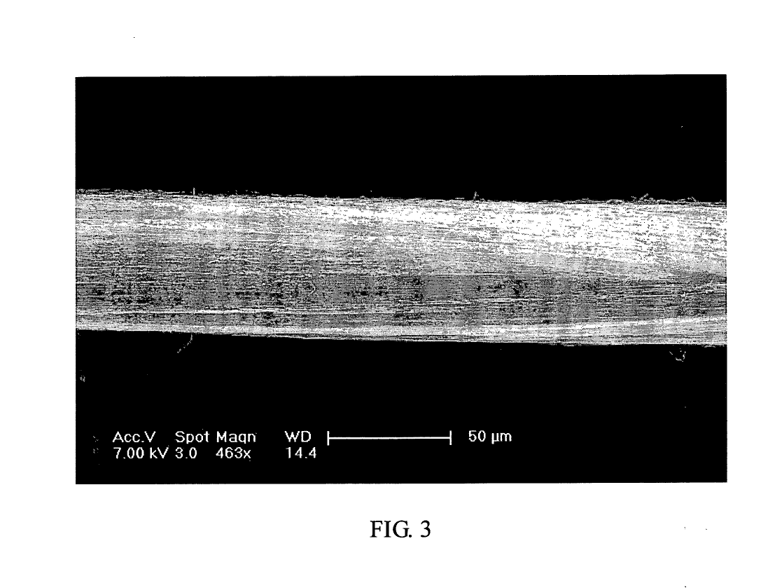

The untwisted carbon nanotube wire can be formed by treating the drawn carbon nanotube film with an organic solvent. Specifically, the drawn carbon nanotube film is treated by applying the organic solvent to the drawn carbon nanotube film to soak the entire surface of the drawn carbon nanotube film. After being soaked by the organic solvent, the adjacent paralleled carbon nanotubes in the drawn carbon nanotube film will bundle together, due to the surface tension of the organic solvent when the organic solvent volatilizes. Thus, the drawn carbon nanotube film will be shrunk into untwisted carbon nanotube wire. The organic solvent is volatile. Referring to FIG. 3, the untwisted carbon nanotube wire includes a plurality of carbon nanotubes substantially oriented along a same direction (e.g., a direction along the length of the untwisted carbon nanotube wire). The carbon nanotubes are substantially parallel to the axis of the untwisted carbon nanotube wire. Length of the untwisted carbon nanotube wire can be set as desired. The diameter of an untwisted carbon nanotube wire can range from about 0.5 nanometers to about 100 micrometers. In one embodiment, the diameter of the untwisted carbon nanotube wire is about 50 micrometers. Examples of the untwisted carbon nanotube wire is taught by US Patent Application Publication US 2007/0166223 to Jiang et al.

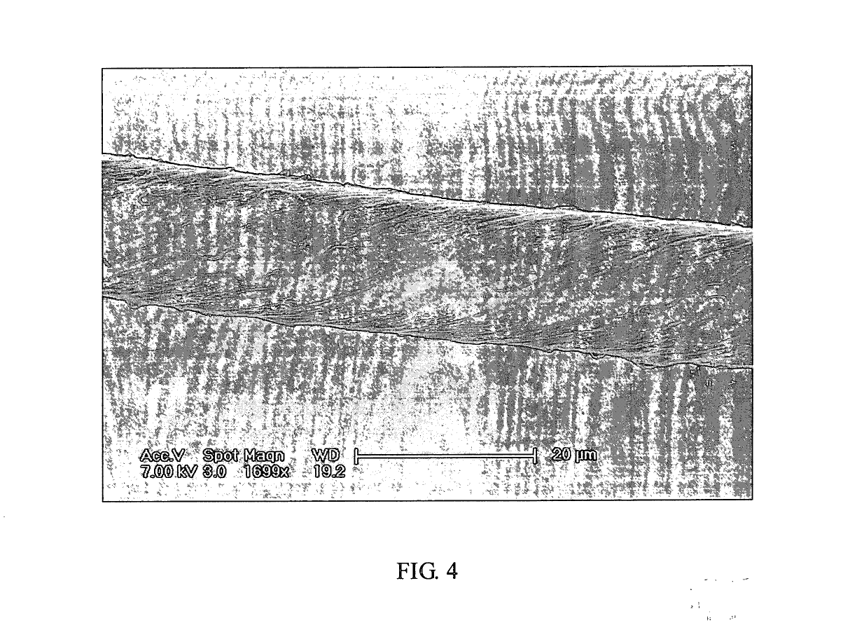

The twisted carbon nanotube wire can be formed by twisting a drawn carbon nanotube film by using a mechanical force to turn the two ends of the drawn carbon nanotube film in opposite directions. Referring to FIG. 4, the twisted carbon nanotube wire includes a plurality of carbon nanotubes oriented around an axial direction of the twisted carbon nanotube wire. The carbon nanotubes are spirally aligned around the axis of the carbon nanotube twisted wire. Length of the carbon nanotube wire can be set as desired. The diameter of the twisted carbon nanotube wire can range from about 0.5 nanometers to about 100 micrometers. Further, the twisted carbon nanotube wire can be treated with a volatile organic solvent, before or after being twisted. After being soaked by the organic solvent, the adjacent paralleled carbon nanotubes in the twisted carbon nanotube wire will bundle together, due to the surface tension of the organic solvent when the organic solvent volatilizes. The specific surface area of the twisted carbon nanotube wire will decrease, and the density and strength of the twisted carbon nanotube wire will increase.

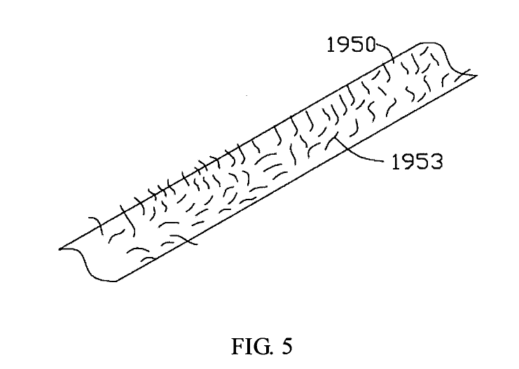

Referring to FIG. 5, carbon nanotubes 1953 on an outer surface 1950 of the carbon nanotube wire has a first portion and a second portion. The first portion is fixed on the outer surface 1950, and the second portion extends out of the outer surface 1950. A part of the second portion of the carbon nanotubes 1953 may point to the substrate 197. If there is no substrate 197 in the reactor chamber 19, a part of the second portion of the carbon nanotubes 1953 can point to the supporter 199.

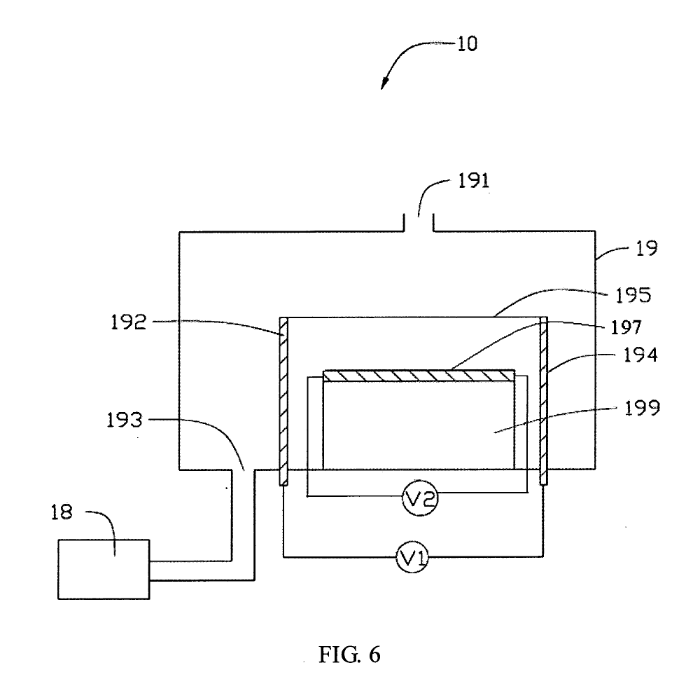

Referring to FIG. 6, a voltage can be applied on the substrate 197 such that a voltage is higher than that of the least one hot filament 195. Thus, the voltage difference between the at least one hot filament 195 and the substrate 197 can be controlled. The carbon nanotubes 1953 on the outer surface 1950 of the carbon nanotube wire can emit electrons to bombard the substrate 199. The electron bombardment of the substrate 197 can allow the reacting gas to react easily and produce carbon atoms to form the diamond film on the substrate 197.

Referring to FIG. 2, one embodiment of a method for forming a diamond film using the device 10 includes:
(a) providing the substrate 197 and treating the substrate 197;
(b) providing the device 10 and positioning the substrate 197 into the reactor chamber 19; and
(c) forming a diamond film on the substrate 197 using a method of HFCVD.

In step (a), the substrate 197 can be treated with a diameter of about 0.5 micron diamond powder grinding for about 1 hour to about 2 hours, then placed in acetone solution in the ultrasonic wave for about 10 minutes to about 20 minutes. The material of the substrate 197 can be a material with a high temperature resistance and chemically stable performance. For example, the substrate 197 may be made of quartz, ceramic, stainless steel or the like. In one embodiment, the substrate 197 is a tungsten round sheet with a diameter of about 90 millimeters and a thickness of about 3 millimeters.

In step (b), the substrate 197 is positioned on the supporter 199 and facing the hot filament 195.

In step (c), one embodiment of a method for forming the diamond film on the substrate includes:
(c1) creating a vacuum in the reactor chamber 19 via the vacuum pump 18;
(c2) applying a voltage on the hot filament 195 to heat the hot filament 195 to a temperature of about 2200° C.; and
(c3) introducing a mixture of hydrocarbon gas and hydrogen into the reactor chamber 19, controlling the temperature of the substrate 197 at about 900° C., and growing the diamond film on the substrate 197.

In step (c1), any gases remaining within the reactor chamber 19 may be pumped out by the vacuum pump 18.

In step (c3), the hydrocarbon gas can be a hydrocarbon gas, such as ethylene (C₂H₄), methane (CH₄), acetylene (C₂H₂), ethane (C₂H₆), or any combination thereof. In one embodiment, a high purity methane gas diluted with hydrogen gas is introduced into the reactor chamber 19 via the inlet 191, so as to flow over the hot filament 195 and the substrate 197. The ratio of methane to the hydrogen gas may vary between about 0.4:99.6 to about 5.0:95. In one embodiment, conditions for the deposition reaction include a chamber temperature between about 700° C. to about 1050° C., a filament current of about 7 to about 9 amperes (amp), filament and substrate spacing from about 2 to about 15 millimeters (mm), total gas flow ranging from about 30 to about 100 Standard Cubic Centimeter per Minute (sccm), pressure ranging from about 20 to about 120 millibars (mB). Typically, the deposition time ranges from about 30 minutes to hundreds of hours, with a diamond film growth rate in the range of about 1 micron per hour.

The at least one hot filament 195 of the device 10 for forming diamond films includes at least one carbon nanotube wire. The at least one carbon nanotube wire includes a plurality of carbon nanotubes joined with each other via Van der Vaals attractive force. Due to carbon nanotubes having a property of ideal black bodies, the least one hot filament 195 has excellent electrical conductivity, thermal stability, and high thermal radiation efficiency. As an ideal black body structure, the carbon nanotube wire radiates heat when it reaches a temperature of about 200° C. to about 450° C. The radiating efficiency is relatively high. Furthermore, the carbon nanotube is very pure, and does not include other atoms other than carbon, thus the diamond films obtained is pure.

Finally, it is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A device for forming diamond films comprising:
a reactor chamber comprising an inlet and an outlet;
a vacuum pump connected to the outlet of the reactor chamber;
a supporter received in the reactor chamber, and facing the inlet;
at least one filament received in the reactor chamber between the inlet and the supporter, the at least one filament comprising at least one carbon nanotube wire comprising a plurality of carbon nanotubes; and
a first electrode and a second electrode positioned in the reactor chamber and electrically connected to the at least one filament.

2. The device for forming diamond films of claim 1, wherein the carbon nanotubes are aligned end-to-end along an axis of the at least one carbon nanotube wire and joined by van der Waals attractive force between them.

3. The device for forming diamond films of claim 2, wherein the at least one carbon nanotube wire is an untwisted carbon nanotube wire, the carbon nanotubes of the untwisted carbon nanotube wire are substantially oriented along the axis of the untwisted carbon nanotube wire.

4. The device for forming diamond films of claim 3, wherein the carbon nanotubes are substantially parallel to a length direction of the untwisted carbon nanotube wire.

5. The device for forming diamond films of claim 2, wherein the at least one carbon nanotube wire is a twisted carbon nanotube wire, the carbon nanotubes of the twisted carbon nanotube wire are substantially oriented around the axis of the twisted carbon nanotube wire.

6. The device for forming diamond films of claim 5, wherein the carbon nanotubes are spirally aligned around the axis of the carbon nanotube twisted wire.

7. The device for forming diamond films of claim 1, wherein the at least one carbon nanotube wire has an outer surface, the carbon nanotubes on the outer surface have a first portion fixed on the outer surface, and a second portion extending out of the at least one carbon nanotube wire.

8. The device for forming diamond films of claim 7, wherein a part of the second portion of the carbon nanotubes is pointed to the supporter.

9. The device for forming diamond films of claim 1, wherein one portion of the first and second electrodes is fixed on and electrically insulated from the reactor chamber, and another portion of the first and the second electrodes is connected to the at least one filament.

10. The device for forming diamond films of claim 9, wherein the at least one filament is supported via the first electrode and the second electrode and located in front of the inlet

11. A device for forming diamond films comprising:
a reactor chamber comprising an inlet and an outlet;
a vacuum pump in controlled communication with the reactor chamber via the outlet;
a supporter received in the reactor chamber and facing the inlet;
at least one filament received in the reactor chamber and positioned between the inlet and the supporter, the at least one filament comprising at least one carbon nanotube wire comprising a plurality of carbon nanotubes;
a substrate being located on the supporter and facing the at least one filament.

12. The device for forming diamond films of claim 11, wherein the carbon nanotubes are aligned end-to-end along an axis of the at least one carbon nanotube wire and joined by van der Waals attractive force between them.

13. The device for forming diamond films of claim 12, wherein the at least one carbon nanotube wire is an untwisted carbon nanotube wire, the carbon nanotubes of the untwisted carbon nanotube wire are substantially oriented along the axis of the untwisted carbon nanotube wire.

14. The device for forming diamond films of claim 13, wherein the carbon nanotubes are substantially parallel to a length direction of the untwisted carbon nanotube wire.

15. The device for forming diamond films of claim 12, wherein the at least one carbon nanotube wire is a twisted carbon nanotube wire, the carbon nanotubes of the twisted carbon nanotube wire are substantially oriented around the axis of the twisted carbon nanotube wire.

16. The device for forming diamond films of claim 15, wherein the carbon nanotubes are spirally aligned around the axis of the carbon nanotube twisted wire.

17. The device for forming diamond films of claim 11, wherein the at least one carbon nanotube wire has an outer surface, the carbon nanotubes on the outer surface have a first portion fixed on the outer surface, and a second portion extending out of the at least one carbon nanotube wire; a part of the second portion of the carbon nanotubes points to the substrate.

18. The device for forming diamond films of claim 17, wherein the carbon nanotubes emit electrons to bombard the substrate when the substrate has a voltage higher than that of the at least one filament.
